(19) United States
(12) Patent Application Publication
(10) Pub. No.: US 2022/0415662 A1
(43) Pub. Date: Dec. 29, 2022

(54) METHOD FOR PRODUCING PILLAR-SHAPED SEMICONDUCTOR DEVICE

(71) Applicant: Unisantis Electronics Singapore Pte. Ltd., Singapore (SG)

(72) Inventor: Nozomu HARADA, Tokyo (JP)

(21) Appl. No.: 17/902,484

(22) Filed: Sep. 2, 2022

Related U.S. Application Data
(63) Continuation of application No. PCT/JP2020/009179, filed on Mar. 4, 2020.

(51) Int. Cl. H01L 21/308; H01L 21/02

(52) U.S. Cl. CPC H01L 21/3086; H01L 21/02532; H01L 21/0262; H01L 21/02614

(57) ABSTRACT

A first mask material layer on a Si pillar 7a and a first material layer around a side surface of a top portion of the Si pillar 7a are formed. A second material layer is then formed on an outer periphery of the first material layer. The first mask material layer and the first material layer are then etched by using the second material layer as a mask. A thin SiGe layer, a p⁺ layer 23a, and a SiO₂ layer 24a are then formed in a recessed portion formed around the Si pillar 7a. The exposed side surface of the thin SiGe layer is oxidized to form a SiO₂ layer 26a. A TiN layer and a W layer, which are gate conductor layers, are etched by using the SiO₂ layers 24a and 26a as masks to form a TiN layer 29a and a W layer 30a. In plan view, the Si pillar 7a, the p⁺ layer 23a with a small diode junction resistance, and the TiN layer 29a and the W layer 30a, which are gate line conductor layers, thus have a self-alignment relationship, and the p⁺ layer 23a and the TiN layer 29a are self-aligned with each other with the HfO₂ layer 28 and the SiO₂ layer 26a therebetween in the vertical direction.

### CROSS REFERENCES TO RELATED APPLICATIONS

The present application is a continuation application of PCT/JP2020/009179, filed Mar. 4, 2020, the entire contents of which are incorporated herein by reference.

### BACKGROUND OF THE INVENTION

### 1. Field of the Invention

The present invention relates to a method for producing a pillar-shaped semiconductor device, particularly a pillar-shaped semiconductor device having a surrounding gate transistor (SGT).

### 2. Description of the Related Art

In recent years, there has been a need to further improve the density and performance of SGT-including semiconductor devices.

In planar MOS transistors, the channel of a p- or n-channel MOS transistor is formed in a horizontal direction along the surface of a semiconductor substrate between the source and the drain. In contrast, the channel of an SGT is formed in a direction vertical to the surface of a semiconductor substrate (see, for example, Japanese Unexamined Patent Application Publication No. 2-188966; and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)).

FIG. 5 is a schematic structural view of an re-channel SGT. A p-type or i-type (intrinsic) Si pillar 115 (hereafter a silicon semiconductor pillar is referred to as a “Si pillar”) has n⁺ regions 116a and 116b in its upper and lower portions. When one of the n⁺ regions 116a and 116b functions as a source, the other functions as a drain. A portion of the Si pillar 115 between the source and drain n⁺ regions 116a and 116b is a channel region 117. A gate insulating layer 118 is formed so as to surround the channel region 117, and a gate conductor layer 119 is formed so as to surround the gate insulating layer 118. In the SGT, the source and drain n⁺ regions 116a and 116b, the channel region 117, the gate insulating layer 118, and the gate conductor layer 119 are formed in the single Si pillar 115. Thus, the occupied area on the surface of the SGT appears to correspond to the area occupied by a single source or drain n⁺ region of a planar MOS transistor. Therefore, SGT-including circuit chips can have a smaller chip size than circuit chips including planar MOS transistors.

FIG. 6 is a cross-sectional view of an SGT-including CMOS inverter circuit (e.g., see FIG. 38(b) in U.S. Patent Application Publication No. 2010/0264484). In the CMOS inverter circuit, an i layer 121 (an “i layer” refers to an intrinsic Si layer) is formed on an insulating layer substrate 120, and a Si pillar SP1 for a p-channel SGT and a Si pillar SP2 for an n-channel SGT are formed on the i layer 121. A drain p⁺ region 122 of the p-channel SGT is formed in the same layer as the i layer 121 so as to surround a lower portion of the Si pillar SP1 in plan view. A drain n⁺ region 123 of the n-channel SGT is formed in the same layer as the i layer 121 so as to surround a lower portion of the Si pillar SP2 in plan view. A source p⁺ region 124 of the p-channel SGT is formed in a top portion of the Si pillar SP1, and a source n⁺ region 125 of the re-channel SGT is formed in a top portion of the Si pillar SP2. Gate insulating layers 126a and 126b are formed so as to surround the Si pillars SP1 and SP2 and extend from the upper surfaces of the drain p⁺ region 122 and the drain n⁺ region 123. A gate conductor layer 127a of the p-channel SGT and a gate conductor layer 127b of the n-channel SGT are formed so as to surround the gate insulating layers 126a and 126b. Sidewall nitride films 128a and 128b, which are insulating layers, are formed so as to surround the gate conductor layers 127a and 127b. Similarly, sidewall nitride films 128c and 128d, which are insulating layers, are formed so as to surround a p⁺ region and an n⁺ region in the top portions of the Si pillars SP1 and SP2. The drain p⁺ region 122 of the p-channel SGT and the drain n⁺ region 123 of the n-channel SGT are connected to each other through a silicide layer 129b. A silicide layer 129a is formed on the source p⁺ region 124 of the p-channel SGT, and a silicide layer 129c is formed on the source n⁺ region 125 of the n-channel SGT. Furthermore, silicide layers 129d and 129e are formed on the top portions of the gate conductor layers 127a and 127b. An i layer 130a of the Si pillar SP1 between the drain p⁺ region 122 and the source p⁺ region 124 functions as a channel of the p-channel SGT. An i layer 130b of the Si pillar SP2 between the drain n⁺ region 123 and the source n⁺ region 125 functions as a channel of the n-channel SGT. A SiO₂ layer 131 is formed so as to cover the insulating layer substrate 120, the i layer 121, and the Si pillars SP1 and SP2. Furthermore, contact holes 132a, 132b, and 132c, which pass through the SiO₂ layer 131, are formed on the Si pillars SP1 and SP2, the drain p⁺ region 122 of the p-channel SGT, and the drain n⁺ region 123 of the n-channel SGT. A power supply wiring metal layer Vd on the SiO₂ layer 131 is connected to the source p⁺ region 124 of the p-channel SGT and the silicide layer 129a through the contact hole 132a. An output wiring metal layer Vo on the SiO₂ layer 131 is connected to the drain p⁺ region 122 of the p-channel SGT, the drain n⁺ region 123 of the n-channel SGT, and the silicide layer 129b through the contact hole 132b. Furthermore, a ground wiring metal layer Vs on the SiO₂ layer 131 is connected to the source n⁺ region 125 of the re-channel SGT and the silicide layer 129c through the contact hole 132c.

The gate conductor layer 127a of the p-channel SGT and the gate conductor layer 127b of the n-channel SGT are connected to an input wiring metal layer (not shown) while being connected to each other. In this CMOS inverter circuit, the p-channel SGT and the n-channel SGT are formed in the Si pillars SP1 and SP2, respectively. Therefore, the circuit area is reduced in plan view in the vertical direction. As a result, the circuit has a smaller size than CMOS inverter circuits including known planar MOS transistors. The use of SGTs can reduce the sizes of many circuits. There is thus a need to achieve size reduction and performance improvement of circuits by using these SGTs. (for example, C. Y. Ting, V. J. Vivalda, and H. G. Schaefer: “Study of planarized sputter-deposited SiO2”, J. Vac. Sci. Technol, 15(3), May/June (1978); V. Probst, H. Schaber, A. Mitwalsky. and H. Kabza: “WSi2 and CoSi2 as diffusion sources for shallow-junction formation in silicon”, J. Appl. Phys. Vol. 70(2), No. 15, pp. 708-719 (1991); and Tadashi Shibata, Susumu Kohyama and Hisakazu Iizuka: “A New Field Isolation Technology for High Density MOS LSI”, Japanese Journal of Applied Physics, Vol. 18, pp. 263-267 (1979)).

### SUMMARY OF THE INVENTION

The present invention is directed to a method for producing an SGT-including semiconductor device for improving the density and performance of circuits.

A method for producing a pillar-shaped semiconductor device according to a first aspect of the present invention includes:

a step of forming a first semiconductor pillar on a substrate, the first semiconductor pillar having a first material layer on a top portion thereof;

a step of forming a second material layer in plan view around a side surface of the first material layer and a side surface of the top portion of the first semiconductor pillar;

a step of forming a third material layer on an outer periphery of the second material layer;

a step of discharging the first material layer and the second material layer to form a first recessed portion around the top portion of the first semiconductor pillar;

a step of forming a first semiconductor layer composed of one or more layers in the first recessed portion, the first semiconductor layer being in contact with a side surface of the first recessed portion and having an upper surface positioned lower than an upper surface of the first recessed portion;

a step of forming a fourth material layer on the first semiconductor layer, the fourth material layer having an upper surface flush with an upper surface of the third material layer;

a step of discharging the third material layer;

a step of oxidizing an exposed surface layer of the first semiconductor layer to form a first oxide layer; and

a step of etching a conductor layer around the first semiconductor pillar by using the fourth material layer and the first oxide layer as masks to form a first gate conductor layer, the conductor layer being composed of one or more layers,

wherein the first semiconductor layer functions as a source or drain, and a first gate insulating layer is disposed between the first semiconductor pillar and the first gate conductor layer.

At least the surface layer of the first semiconductor layer is preferably made of a material having a higher oxidation rate than the first semiconductor pillar.

The first semiconductor layer may include a second semiconductor layer and a third semiconductor layer from outside.

The second semiconductor layer may be made of a material having a higher oxidation rate than the first semiconductor pillar.

At least the third semiconductor layer may contain a donor or acceptor impurity.

The method for producing a pillar-shaped semiconductor device may further include:

a step of forming a dummy gate material layer around the first semiconductor pillar;

a step of forming the second material layer and the third material layer on or above the dummy gate material layer;

a step of discharging the first material layer and the second material layer to form the first recessed portion, and discharging the dummy gate material layer after forming the first semiconductor layer and the fourth material layer;

a step of forming the first oxide layer on the exposed surface layer of the first semiconductor layer and, at the same time, forming a second oxide layer on the exposed surface layer of the first semiconductor pillar;

a step of forming the first gate insulating layer and the conductor layer around the first semiconductor pillar; and

a step of etching the conductor layer around the first semiconductor pillar by using the fourth material layer and the first oxide layer as masks to form the first gate conductor layer.

The method for producing a pillar-shaped semiconductor device may further include:

a step of forming a first insulating layer on the dummy gate material layer before forming the second material layer; and

a step of etching the first insulating layer and the conductor layer around the first semiconductor pillar by using the fourth material layer and the first oxide layer as masks to form the first gate conductor layer.

The method for producing a pillar-shaped semiconductor device may further include:

a step of exposing the first material layer and the top portion of the first semiconductor pillar and forming the first gate insulating layer and the conductor layer around a side surface of the semiconductor pillar below the top portion of the first semiconductor pillar;

a step of forming a second insulating layer on the conductor layer; and

a step of forming the second material layer on the second insulating layer.

The method for producing a pillar-shaped semiconductor device may include:

a step of forming the first semiconductor layer and the fourth material layer after forming the second insulating layer;

a step of oxidizing a side surface of the first semiconductor layer to form a third oxide layer; and

a step of etching the second insulating layer and the conductor layer by using the first material layer and the third material layer as masks to form the first gate conductor layer.

The method for producing a pillar-shaped semiconductor device may further include:

a step of forming a first mask material layer on the fourth material layer, the first mask material layer at least partially overlapping the fourth material layer in plan view; and

a step of etching the conductor layer by using the first oxide layer, the fourth material layer, and the first mask material layer as masks to form the first gate conductor layer.

The method for producing a pillar-shaped semiconductor device may further include:

a step of forming a second semiconductor pillar adjacent to the first semiconductor pillar;

a step of forming a second recessed portion around a top portion of the second semiconductor pillar by the same step as that of forming the first recessed portion;

a step of forming a fourth semiconductor layer in the second recessed portion so as to cover the top portion of the second semiconductor pillar by the same step as that of forming the first semiconductor layer, and forming a fifth material layer on the fourth semiconductor layer, the fifth material layer having an upper surface flush with an upper surface of the fourth material layer;

a step of oxidizing the first semiconductor layer to form the first oxide layer and, at the same time, oxidizing the fourth semiconductor layer to form a third oxide layer; and

a step of etching the conductor layer by using the first oxide layer, the fourth material layer, the fifth material layer, and the third oxide layer as masks to form the first gate conductor layer.

The method for producing a pillar-shaped semiconductor device may further include:

a step of forming a second mask material layer on the fourth material layer and the fifth material layer, the second mask material layer at least partially overlapping the fourth material layer and the fifth material layer in plan view; and

a step of etching the conductor layer by using the first oxide layer, the fourth material layer, the third oxide layer, the fifth material layer, and the second mask material layer as masks to form the first gate conductor layer.

The present invention can provide a method for producing an SGT-including semiconductor device for improving the density and performance of circuits.

### BRIEF DESCRIPTION OF THE DRAWINGS

FIGS. 1AA, 1AB, and 1AC are a plan view and cross-sectional views of a CMOS inverter circuit for describing a method for producing an SGT-including semiconductor device according to a first embodiment.

FIGS. 1BA, 1BB, and 1BC are a plan view and cross-sectional views of the CMOS inverter circuit for describing the method for producing the SGT-including semiconductor device according to the first embodiment.

FIGS. 1CA, 1CB, and 1CC are a plan view and cross-sectional views of the CMOS inverter circuit for describing the method for producing the SGT-including semiconductor device according to the first embodiment.

FIGS. 1DA, 1DB, and 1DC are a plan view and cross-sectional views of the CMOS inverter circuit for describing the method for producing the SGT-including semiconductor device according to the first embodiment.

FIGS. 1EA, 1EB, and 1EC are a plan view and cross-sectional views of the CMOS inverter circuit for describing the method for producing the SGT-including semiconductor device according to the first embodiment.

FIGS. 1FA, 1FB, and 1FC are a plan view and cross-sectional views of the CMOS inverter circuit for describing the method for producing the SGT-including semiconductor device according to the first embodiment.

FIGS. 1GA, GB, and 1GC are a plan view and cross-sectional views of the CMOS inverter circuit for describing the method for producing the SGT-including semiconductor device according to the first embodiment.

FIGS. 1HA, 1HB, and 1HC are a plan view and cross-sectional views of the CMOS inverter circuit for describing the method for producing the SGT-including semiconductor device according to the first embodiment.

FIGS. 1IA, 1IB, and 1IC are a plan view and cross-sectional views of the CMOS inverter circuit for describing the method for producing the SGT-including semiconductor device according to the first embodiment.

FIGS. 1JA, 1JB, and 1JC are a plan view and cross-sectional views of the CMOS inverter circuit for describing the method for producing the SGT-including semiconductor device according to the first embodiment.

FIGS. 1KA, 1KB, and 1KC are a plan view and cross-sectional views of the CMOS inverter circuit for describing the method for producing the SGT-including semiconductor device according to the first embodiment.

FIGS. 1LA, 1LB, and 1LC are a plan view and cross-sectional views of the CMOS inverter circuit for describing the method for producing the SGT-including semiconductor device according to the first embodiment.

FIGS. 1MA, 1MB, 1MC are a plan view and cross-sectional views of the CMOS inverter circuit for describing the method for producing the SGT-including semiconductor device according to the first embodiment.

FIGS. 1NA, 1NB, and 1NC are a plan view and cross-sectional views of the CMOS inverter circuit for describing the method for producing the SGT-including semiconductor device according to the first embodiment.

FIGS. 1OA, 1OB, and 1OC are a plan view and cross-sectional views of the CMOS inverter circuit for describing the method for producing the SGT-including semiconductor device according to the first embodiment.

FIGS. 1PA, 1PB, and 1PC are a plan view and cross-sectional views of the CMOS inverter circuit for describing the method for producing the SGT-including semiconductor device according to the first embodiment.

FIGS. 1QA, 1QB, and 1QC are a plan view and cross-sectional views of the CMOS inverter circuit for describing the method for producing the SGT-including semiconductor device according to the first embodiment.

FIGS. 1RA, 1RB, and 1RC are a plan view and cross-sectional views of the CMOS inverter circuit for describing the method for producing the SGT-including semiconductor device according to the first embodiment.

FIGS. 2AA, 2AB, and 2AC are a plan view and cross-sectional views of a CMOS inverter circuit for describing a method for producing an SGT-including semiconductor device according to a second embodiment.

FIGS. 2BA, 2BB, and 2BC are a plan view and cross-sectional views of the CMOS inverter circuit for describing the method for producing the SGT-including semiconductor device according to the second embodiment.

FIGS. 2CA, 2CB, and 2CC are a plan view and cross-sectional views of the CMOS inverter circuit for describing the method for producing the SGT-including semiconductor device according to the second embodiment.

FIGS. 2DA, 2DB, and 2DC are a plan view and cross-sectional views of the CMOS inverter circuit for describing the method for producing the SGT-including semiconductor device according to the second embodiment.

FIGS. 2EA, 2EB, and 2EC are a plan view and cross-sectional views of the CMOS inverter circuit for describing the method for producing the SGT-including semiconductor device according to the second embodiment.

FIGS. 3AA, 3AB, and 3AC are a plan view and cross-sectional views of a CMOS inverter circuit for describing a method for producing an SGT-including semiconductor device according to a third embodiment.

FIGS. 3BA, 3BB, and 3BC are a plan view and cross-sectional views of the CMOS inverter circuit for describing the method for producing the SGT-including semiconductor device according to the third embodiment.

FIGS. 3CA, 3CB, and 3CC are a plan view and cross-sectional views of the CMOS inverter circuit for describing the method for producing the SGT-including semiconductor device according to the third embodiment.

FIGS. 4A, 4B, and 4C are a plan view and cross-sectional views of a CMOS inverter circuit for describing a method for producing an SGT-including semiconductor device according to a fourth embodiment.

FIG. 5 is a schematic structural view for describing an SGT known in the related art.

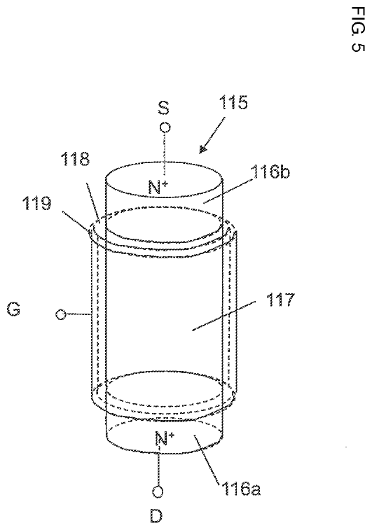

FIG. 6 is a cross-sectional view of a CMOS inverter circuit having SGTs known in the related art.

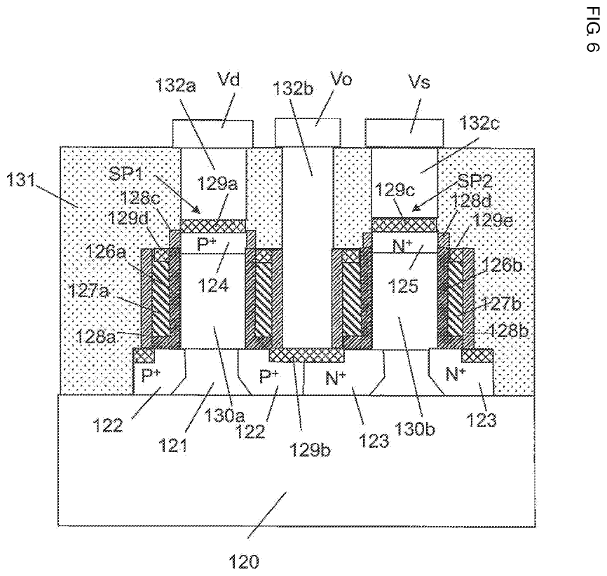

### DESCRIPTION OF THE PREFERRED EMBODIMENTS

A method for producing an SGT-including semiconductor device according to an embodiment of the present invention will be described below with reference to the drawings.

### First Embodiment

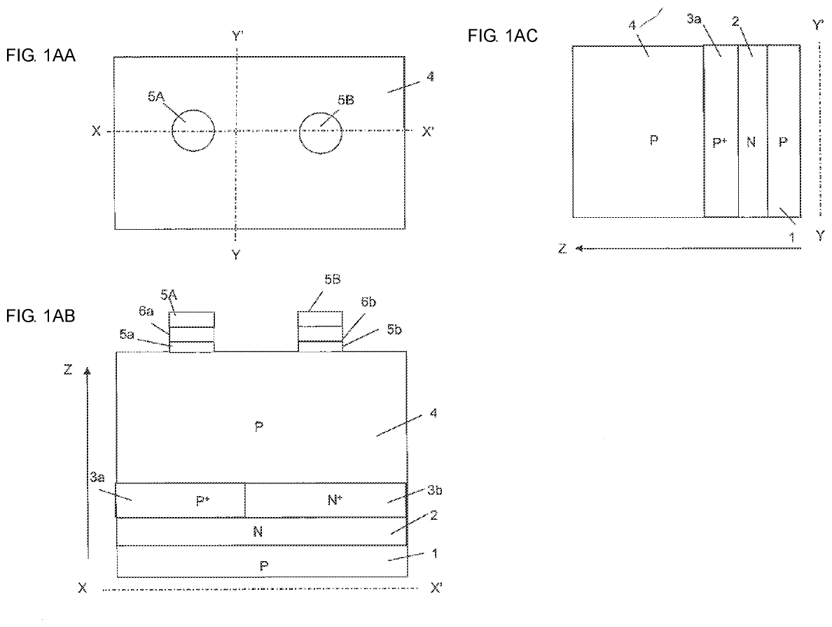

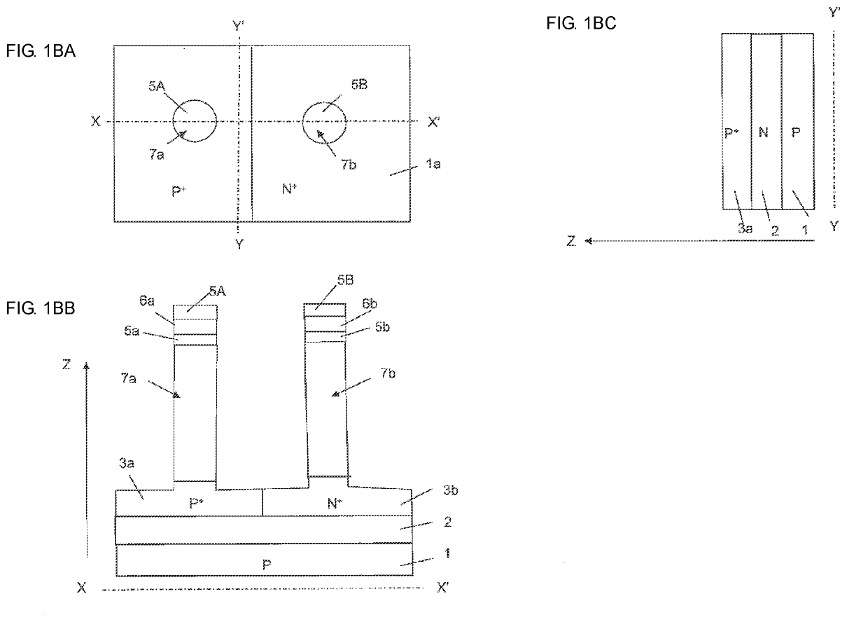

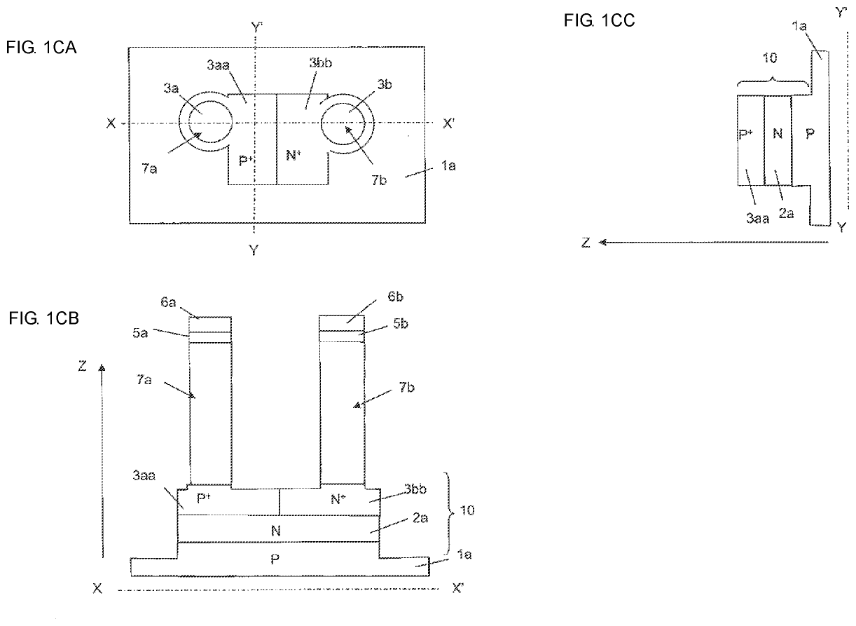

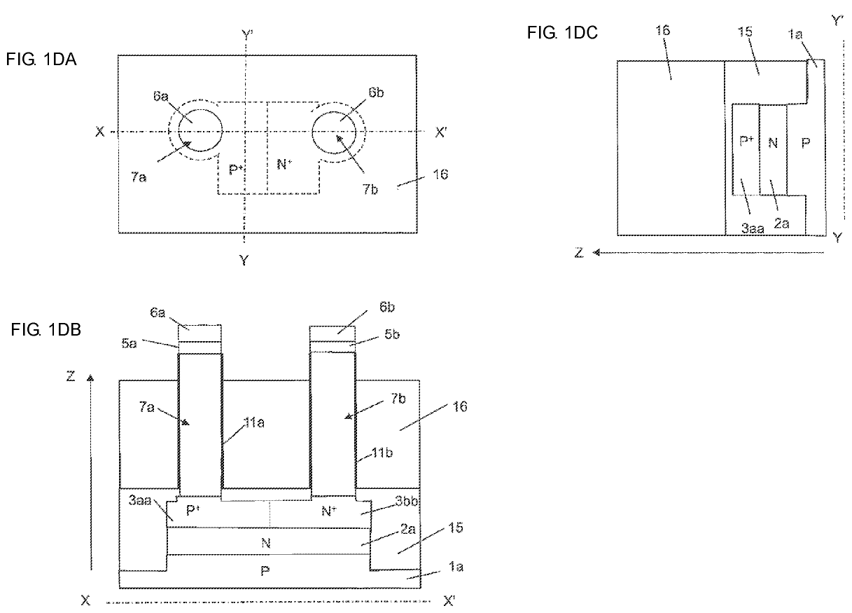

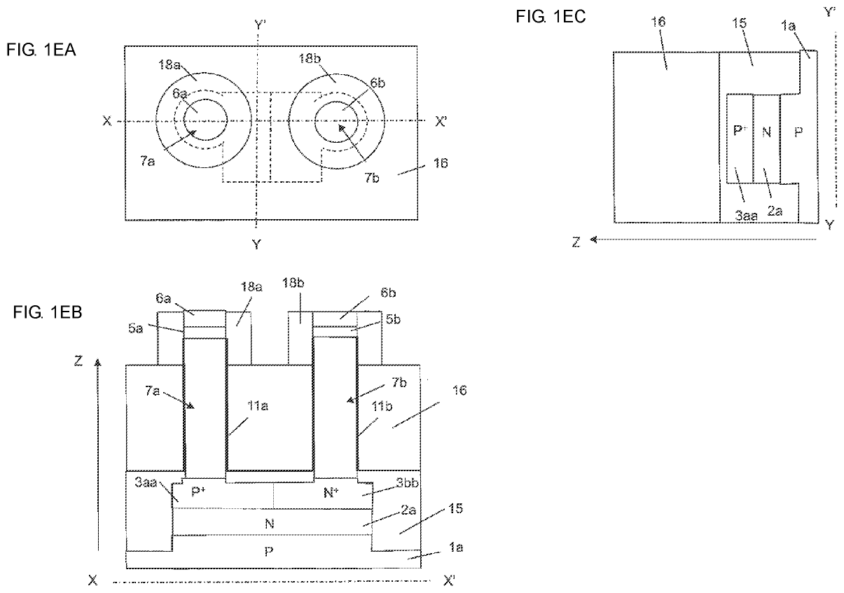

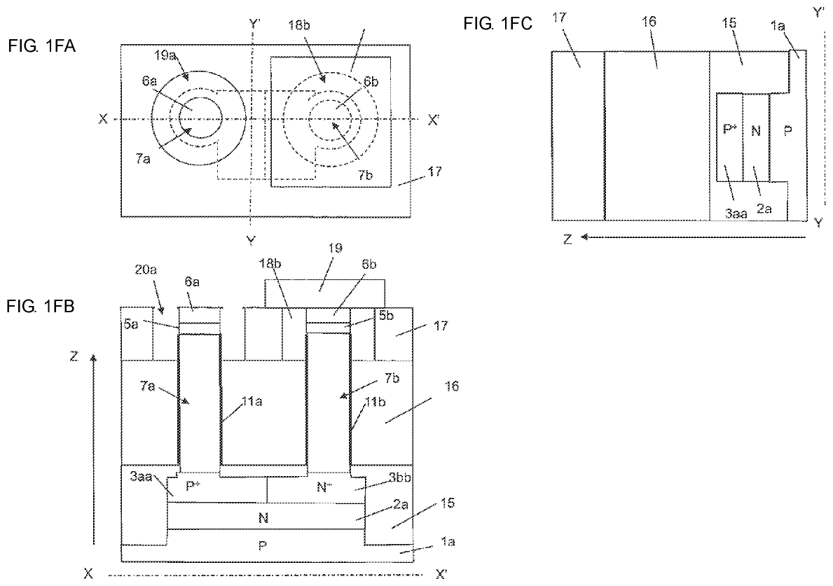

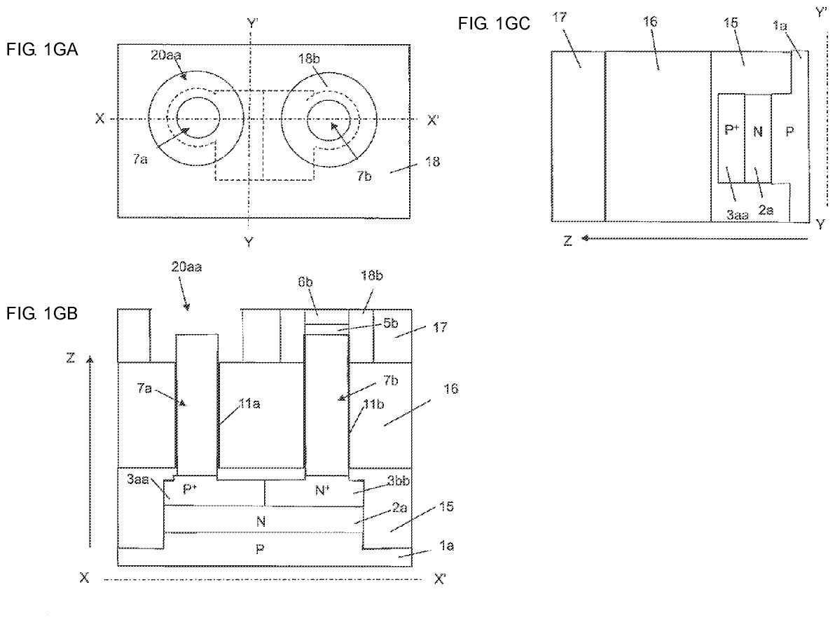

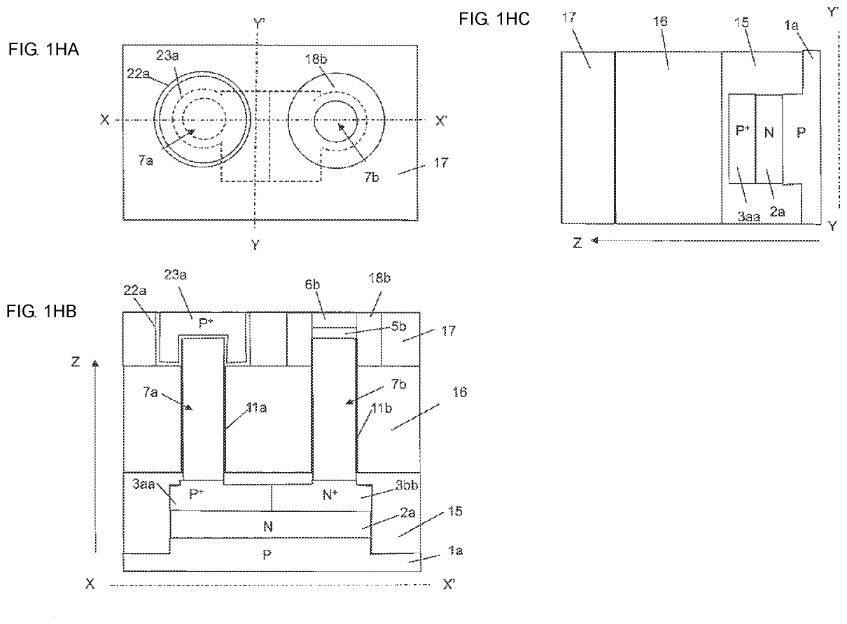

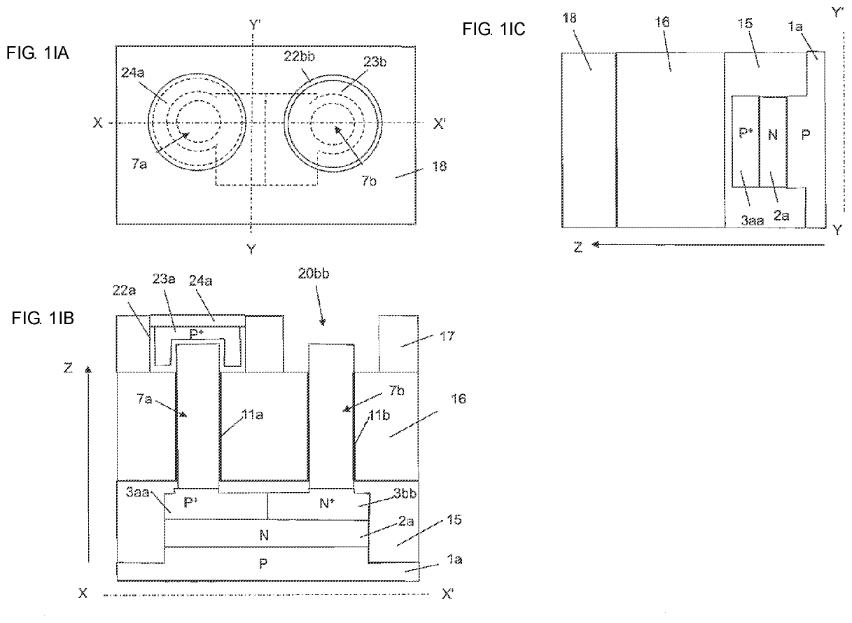

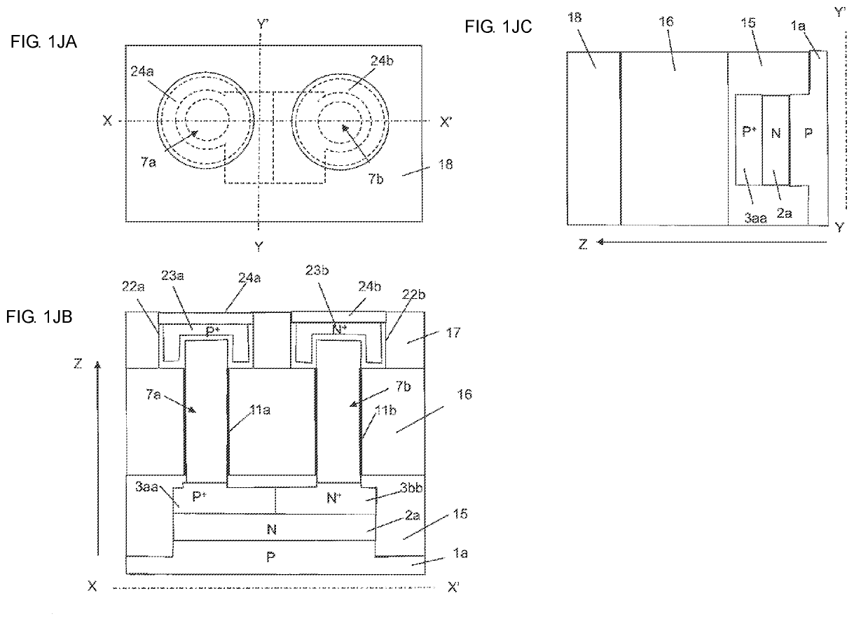

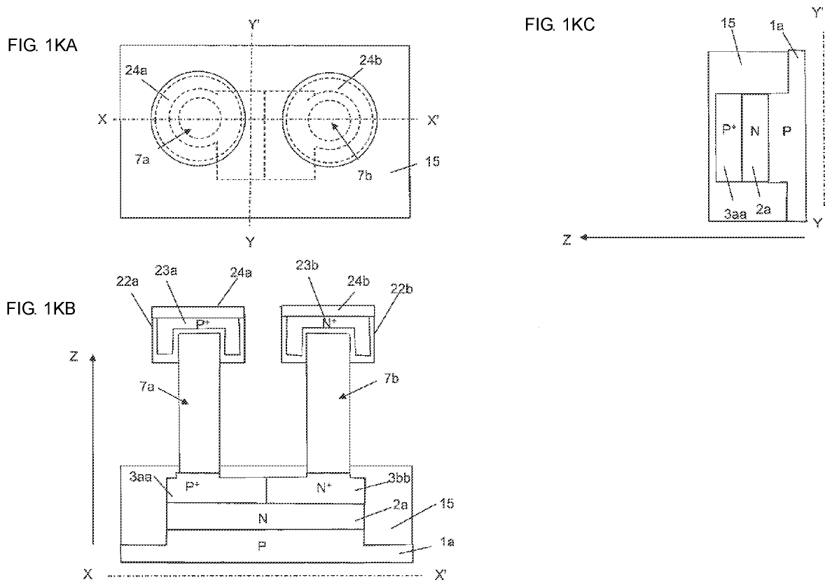

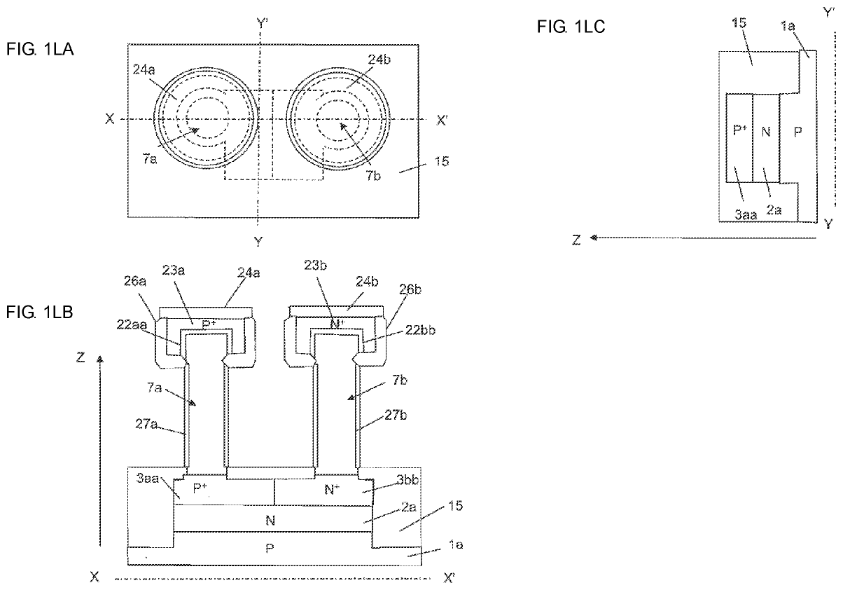

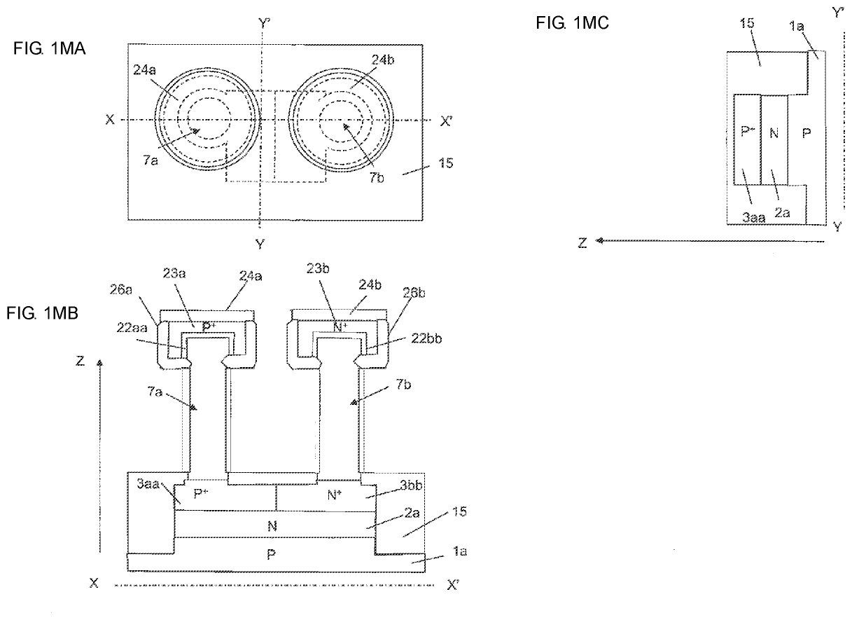

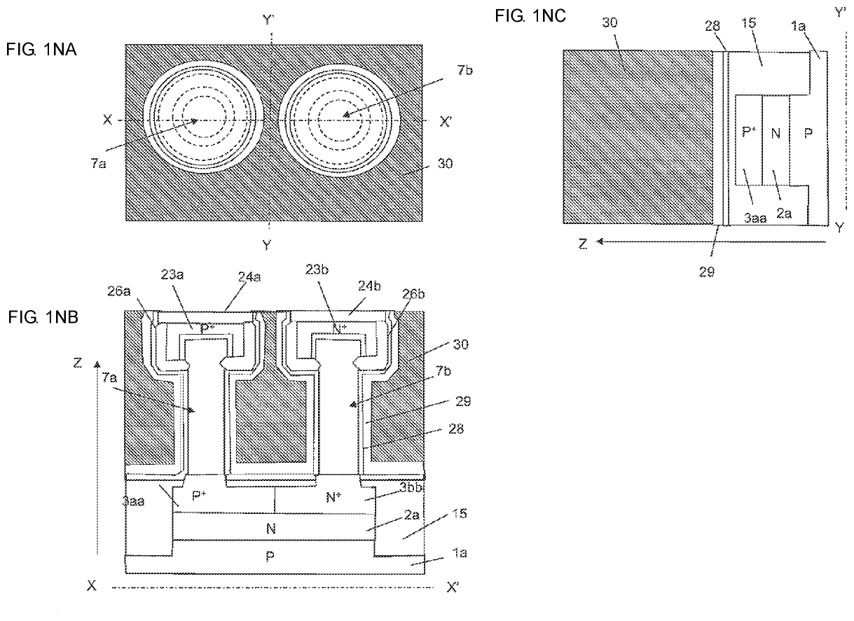

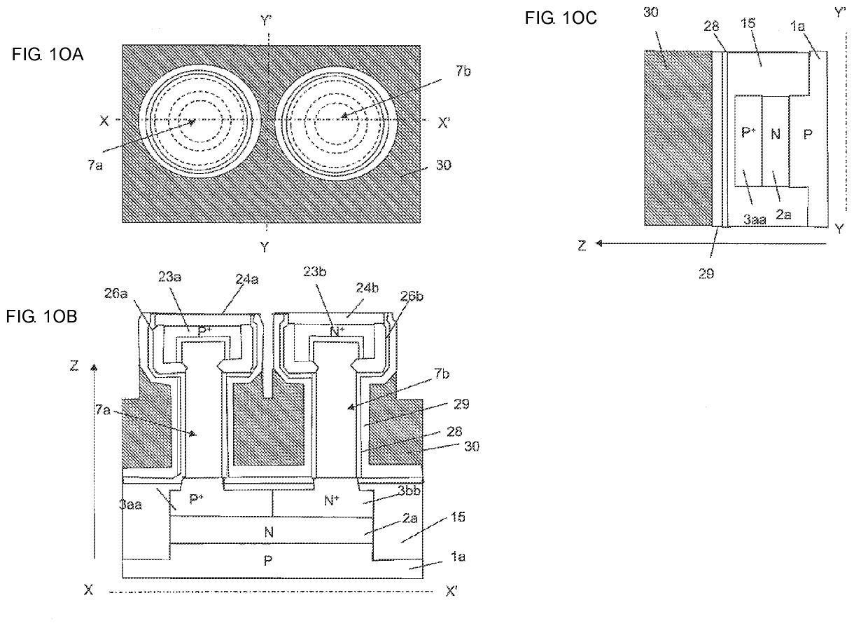

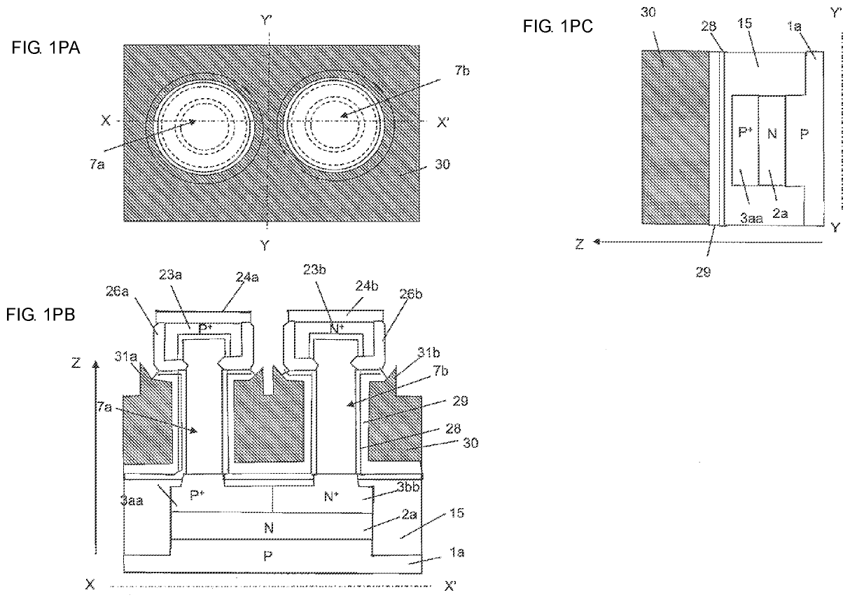

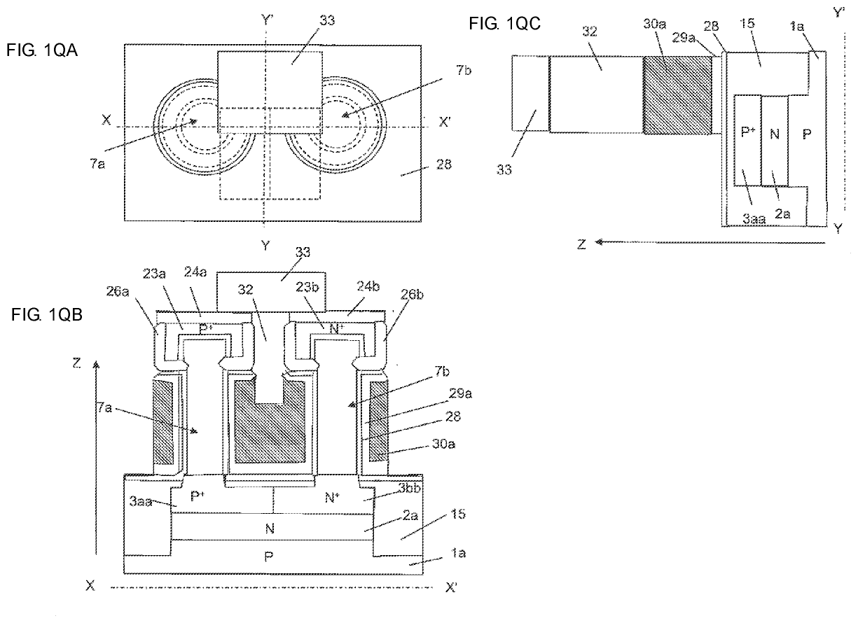

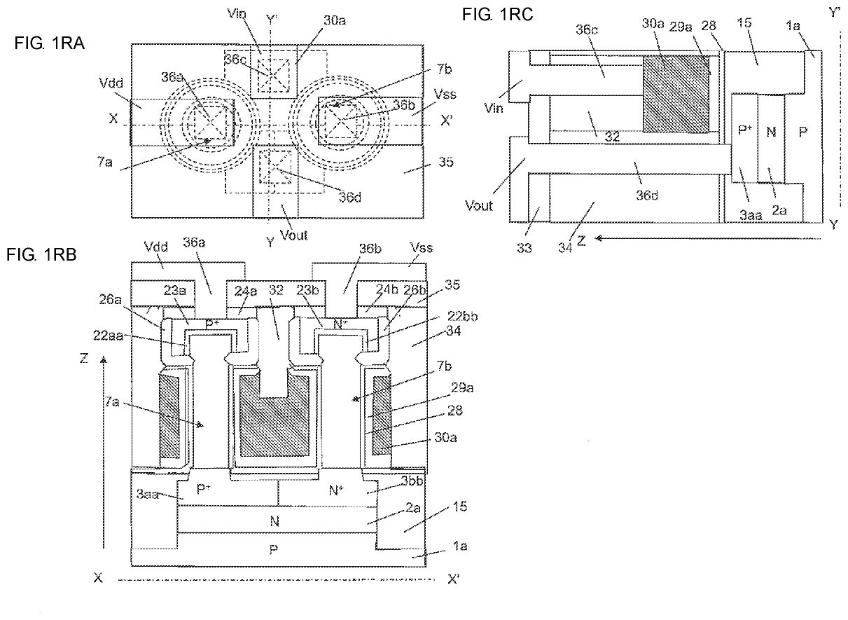

FIGS. 1AA to 1RC illustrate a method for producing an SGT-including CMOS inverter circuit according to a first embodiment of the present invention. The figures suffixed with letter A are plan views, the figures suffixed with letter B are cross-sectional views taken along line X-X′ in the respective figures suffixed with letter A, and the figures suffixed with letter C are cross-sectional views taken along line Y-Y′ in the respective figures suffixed with letter A.

As shown in FIGS. 1AA to 1AC, an n layer 2 is formed on a p-type Si substrate 1 (an example of the substrate in Claims). A p⁺ layer 3a and an n⁺ layer 3b are formed on the n layer 2. A p layer 4 is formed on the p⁺ layer 3a and the n⁺ layer 3b. A SiO₂ layer 5a, a SiN layer 6a, and a SiO₂ layer 5A (three layers, the SiO₂ layer 5a, the SiN layer 6a, and the SiO₂ layer 5A, are examples of the first material layer in Claims), and a SiO₂ layer 5b, a SiN layer 6b, and a SiO₂ layer 5B are formed on the p layer 4. The SiO₂ layer 5a, the SiN layer 6a, and the SiO₂ layer 5A each have a circular shape and overlap one another in plan view. The SiO₂ layer 5b, the SiN layer 6b, and the SiO₂ layer 5B each have a circular shape and overlap one another in plan view. The p⁺ layer 3a and the n⁺ layer 3b may each be, instead of a Si layer, a semiconductor layer made of a material different from Si, such as SiGe or SiC. The SiO₂ layer 5a, the SiN layer 6a, the SiO₂ 5A, the SiO₂ layer 5b, the SiN layer 6b, the SiO₂ layer 5B are used as etching masks in a later process or as stopper layers in the chemical mechanical polishing (CMP) process. The material layers for the SiO₂ layer 5a, the SiN layer 6a, and the SiO₂ 5A, and the SiO₂ layer 5b, the SiN layer 6b, and the SiO₂ layer 5B may each be composed of one or more layers made of other materials, instead of a SiO₂ layer or a SiN layer, as long as the material layers function as etching masks or stopper layers.

Next, as shown in FIGS. 1BA to 1BC, the p layer 4 is etched by using, as masks, the SiO₂ layer 5a, the SiN layer 6a, and the SiO₂ layer 5A, and the SiO₂ layer 5b, the SiN layer 6b, and the SiO₂ layer 5B to form a Si pillar 7a (an example of the first semiconductor pillar in Claims) and a Si pillar 7b (an example of the second semiconductor pillar in Claims). The etching may reach the surface layers of the p⁺ layer 3a and the n⁺ layer 3b.

Next, as shown in FIGS. 1CA to 1CC, a Si pillar base 10 including an upper portion of the p layer substrate 1, an n layer 2a, a p⁺ layer 3aa, and an n⁺ layer 3bb, which are connected to each other, is formed below the Si pillars 7a and 7b. The Si pillar base 10 surrounds the Si pillars 7a and 7b in plan view. In this process, the SiO₂ layers 5A and 5B are discharged by, for example, etching the SiO₂ layers by chemical mechanical polishing (CMP).

Next, as shown in FIGS. 1DA to 1DC, a SiO₂ layer 15 is formed on the outer peripheries of the Si pillar base 10 and the bottom portions of the Si pillars 7a and 7b. Thin SiO₂ layers 11a and 11b are then formed around the Si pillars 7a and 7b. A poly Si layer (not shown) is then formed so as to cover the entire structure. The poly Si layer is then etched by CMP so as to have an upper surface flush with the surface layers of the SiN layers 6a and 6b. The poly Si layer is then etched by reactive ion etching (RIE) so as to have an upper surface positioned adjacent to the top portions of the Si pillars 7a and 7b to form a poly Si layer 16 (an example of the dummy gate material layer in Claims). The exposed SiO₂ layers 11a and 11b on the Si pillars 7a and 7b are then discharged. The thin SiO₂ layers may be formed by other methods, such as atomic layer deposition (ALD). The poly Si layer 16 will be discharged in a later process, and a gate conductor layer will be formed in the region in which the poly Si layer 16 is discharged. The poly Si layer 16 is accordingly used as a dummy gate material layer. The poly Si layer 16 may be formed of another material layer that can functions as a dummy gate material layer, such as a material layer made of amorphous Si.

Next, a SiO₂ layer (not shown) is formed so as to cover the entire structure. As shown in FIGS. 1EA to 1EC, the SiO₂ layer is etched by RIE to form a SiO₂ layer 18a (an example of the second material layer in Claims) and a SiO₂ layer 18b. The SiO₂ layer 18a surrounds a top portion of the Si pillar 7a and the side surfaces of the SiO₂ layer 5a and the SiN layer 6a. The SiO₂ layer 18b surrounds a top portion of the Si pillar 7b and the side surfaces of the SiO₂ layer 5b and the SiN layer 6b. The SiO₂ layers 18a and 18b are accordingly self-aligned with the Si pillars 7a and 7b. The term self-alignment means that the SiO₂ layers 18a and 18b can be formed such that the positional relationship between the Si pillars 7a and 7b and the SiO₂ layers 18a and 18b in plan view is established without mask misalignment in lithography. The SiO₂ layers 18a and 18b are respectively formed around the top portions of the Si pillars 7a and 7b so as to have a substantially uniform width in plan view. In other words, the SiO₂ layers 18a and 18b are left to have a uniform width by etching in accordance with the RIE method. The SiO₂ layers 18a and 18b may be formed by other methods as long as the SiO₂ layers 18a and 18b are self-aligned with the top portions of the Si pillars 7a and 7b. An example of other methods may involve: forming the SiO₂ layers 18a and 18b by using the SiO₂ layer and the SiN layer from below; leaving only the upper SiN layer so as to have a uniform width on the side surfaces of the SiO₂ layers 5a and 5b and the SiN layers 6a and 6b by the RIE method; and etching the lower SiO₂ layers by using the remaining SiN layer as a mask to form SiO₂ layers that have the same function as the SiO₂ layers 18a and 18b.

Next, an aluminum oxide (AlO) layer (not shown) is formed so as to cover the entire structure. As shown in FIGS. 1FA to 1FC, the AlO layer is polished by CMP so as to have an upper surface flush with the upper surfaces of the SiN layers 6a and 6b to form an AlO layer 17 (an example of the third material layer in Claims). A resist layer 19 is formed on the SiO₂ layer 18b and the SiN layer 6b by lithography. The SiO₂ layers 18a and 18b are etched by using the AlO layer 17, the SiN layers 6a and 6b, and the resist layer 19 as masks to form a recessed portion 20a. Since the recessed portion 20a has the same shape as the SiO₂ layer 18a, the recessed portion 20a is self-aligned with the Si pillar 7a. The AlO layer 17 may be another material layer as long as the SiO₂ layers 18a and 18b can be selectively etched by using the SiN layers 6a and 6b as masks. The resist layer 19 may be an inorganic or organic material layer composed of one or more layers.

The SiN layer 6a and the SiO₂ layer 5a are discharged to form a recessed portion 20aa (an example of the first recessed portion in Claims) in which the top portion of the Si pillar 7a is exposed as shown FIGS. 1GA to 1GC. The recessed portion 20aa is self-aligned with the Si pillar 7a. The discharge of the SiN layer 6a and the SiO₂ layer 5a may involve, after forming the AlO layer 17, first discharging the SiN layer 6a, and then discharging the SiO₂ layer 5a together with the SiO₂ layer 18a. Other methods may be used to discharge the SiN layer 6a and the SiO₂ layers 18a and 5a as long as the entire top portion of the Si pillar 7a is exposed.

Next, a thin silicon-germanium (SiGe) layer (not shown) and a p⁺ layer (not shown) made of Si and containing an acceptor impurity are deposited on the entire surface by epitaxial crystal growth. As shown in FIGS. 1HA to 1HC, the SiGe layer and the p⁺ layer are polished by CMP so as to have upper surfaces flush with the upper surface of the AlO layer 17 to form a SiGe layer 22a and a p⁺ layer 23a (a combination of the SiGe layer 22a and the p⁺ layer 23a is an example of the first semiconductor layer in Claims, the SiGe layer 22a is an example of the second semiconductor layer in Claims, and the p⁺ layer 23a is the third semiconductor layer in Claims) in the recessed portion 20aa. The SiGe layer 22a is preferably formed by using a method that can controllably form a thin film with high crystallinity, such as ALD. The SiGe layer may or may not contain an acceptor impurity. Since the SiGe layer 22a and the p⁺ layer 23a are formed in the recessed portion 20aa self-aligned with the Si pillar, the SiGe layer 22a and the p⁺ layer 23a are self-aligned with the Si pillar 7a.

Next, a SiO₂ layer (not shown) is deposited on the entire surface after etching the surface layers of the SiGe layer 22a and the p⁺ layer 23a. As shown in FIGS. 1IA to 1IC, the SiO₂ layer is polished by CMP so as to have an upper surface flush with the upper surface of the AlO layer 17 to form a SiO₂ layer 24a (an example of the fourth material layer in Claims). A recessed portion 20bb (an example of the second recessed portion in Claims) is formed by the same method as that for forming the recessed portion 20aa. The SiO₂ layer 24a may be, for example, a SiN layer, or another material layer composed of one or more layers.

Next, as shown in FIGS. 1JA to 1JC, a SiGe layer 22b and an n⁺ layer 23b (a combination of the SiGe layer 22b and the n⁺ layer 23b is an example of the fourth semiconductor layer in Claims) and a SiO₂ layer 24b (an example of the fifth material layer in Claims) are formed in the recessed portion 20bb so as to cover the top portion of the Si pillar 7b by the same method as that for forming the SiGe layer 22a, the p⁺ layer 23a, and the SiO₂ layer 24a.

Next, as shown in FIGS. 1KA to 1KC, the AlO layer 17, the poly Si layer 16, the SiO₂ layers 11a and 11b are discharged. When the SiO₂ layers 24a and 24b are thicker than the SiO₂ layers 11a and 11b, the SiO₂ layers 24a and 24b are left on the SiGe layers 22a and 22b, the p⁺ layer 23a, and the n⁺ layer 23b. The SiGe layers 22a and 22b, the p⁺ layer 23a, and the n⁺ layer 23b are accordingly self-aligned with the Si pillars 7a and 7b.

Next, as shown in FIGS. 1LA to 1LC, the exposed side surfaces of the Si pillars 7a and 7b and the exposed SiGe layers 22a and 22b are oxidized to form SiO₂ layers 26a (an example of the first oxide layer in Claims), 26b (an example of the third oxide layer in Claims), 27a (an example of the second oxide layer in Claims), and 27b. Since the oxidation rate of SiGe is higher than that of Si, the SiO₂ layers 26a and 26b are thicker than SiO₂ layers 27a and 27b. In FIGS. 1LA to 1LC, the exposed SiGe layers 22a and 22b are entirely oxidized to form the SiO₂ layers 26a and 26b. However, portions of the SiGe layers 22a and 22b in contact with the p⁺ layer 23a and the n⁺ layer 23b may be left.

Next, as shown in FIGS. 1MA to 1MC, the entire SiO₂ layers 27a and 27b and the surface layers of the SiO₂ layers 26a and 26b are etched away. The surface layers of the SiO₂ layers 26a and 26b are left to cover the p⁺ layer 23a and the n⁺ layer 23b.

Next, a HfO₂ layer (not shown), which will serve as a gate insulating layer, and a TiN layer (not shown) and a W layer (not shown), which will serve as gate conductor layers, are deposited by ALD to cover the entire structure. As shown in FIGS. 1NA to 1NC, the W layer, the TiN layer, and the HfO₂ layer are polished by CMP so as to have upper surfaces flush with the upper surfaces of the SiO₂ layers 24a and 24b to form a HfO₂ layer 28, a TiN layer 29, and a W layer 30 (the TiN layer 29 and the W layer 30 are examples of the conductor layer in Claims). A thin oxide film is preferably formed on the side surfaces of the Si pillars 7a and 7b before the HfO₂ layer 28 is deposited.

Next, as shown in FIGS. 10A to 10C, the W layer 30 is etched by RIE so as to have an upper surface positioned lower than the lower surfaces of the SiO₂ layers 26a and 26b connected to the Si pillars 7a and 7b. In this etching, the HfO₂ layer 28, the TiN layer 29, and the SiO₂ layers 24a and 24b are used as etching masks. The HfO₂ layer 28 and the TiN layer 29 overlap one another on the side surfaces of the p⁺ layer 23a and the n⁺ layer 23b. The W layer 30 outside the TiN layer 29 on the outer peripheries of the p⁺ layer 23a and the n⁺ layer 23b in plan view is etched accordingly. The side surfaces of the exposed TiN layer 29 and the HfO₂ layer 28 may be etched by RIE.

Next, as shown in FIGS. 1PA to 1PC, the exposed TiN layer 29 and the HfO₂ layer 28 are etched away. The etching forms projecting W layers 31a and 31b on the outer peripheries of the SiO₂ layers 26a and 26b in plan view.

Next, the W layer 30 is etched by RIE using the SiO₂ layers 24a, 24b, 26a, and 26b as masks. The projecting W layers 31a and 31b are discharged accordingly. As shown in FIGS. 1QA to 1QC, the W layer 30 and the TiN layer 29 are further etched until the upper surface of the W layer is positioned lower than the SiO₂ layers 26a and 26b. A SiN layer (not shown) is then deposited on the entire surface. The SiN layer is then polished by CMP so as to have an upper surface flush with the upper surfaces of the SiO₂ layers 24a and 24b. A mask material layer 33 (an example of the first mask material layer or the second mask material layer in Claims) is then formed. The mask material layer 33 partially overlaps the SiO₂ layers 24a and 24b in plan view. The TiN layer 29 and the W layer 30 are etched by using the mask material layer 33 and the SiO₂ layers 24a, 24b, 26a, and 26b as masks to form a TiN layer 29a and a W layer 30a. The TiN layer 29a and the W layer 30a surround the outer peripheries of the Si pillars 7a and 7b so as to have a uniform width and serve as gate conductor layers connected to each other on the outer peripheries of the Si pillars 7a and 7b.

Next, as shown in FIGS. 1RA to 1RC, a SiO₂ layer (not shown) is deposited on the entire surface. The SiO₂ layer is then polished by CMP so as to have an upper surface flush with the upper surface of a SiN layer 32 to form a SiO₂ layer 34. A SiO₂ layer 35 is then deposited on the entire surface. A contact hole 36a is then formed on the p⁺ layer 23a, a contact hole 36b on the n⁺ layer 23b, a contact hole 36c on a gate line W layer 30a, and a contact hole 36d on the boundary between the p⁺ layer 3aa and the n⁺ layer 3bb. A power supply wiring metal layer Vdd connected to the p⁺ layer 23a through the contact hole 36a, a ground wiring metal layer Vss connected to the n⁺ layer 23b through the contact hole 36b, an input wiring metal layer Vin connected to the gate line W layer 30a through the contact hole 36c, and an output wiring metal layer Vout connected to the p⁺ layer 3aa and the n⁺ layer 3bb through the contact hole 36d are formed. A CMOS inverter circuit is accordingly formed on the p layer substrate 1a.

The thickness and acceptor or donor impurity concentration of thin SiGe layers 22aa and 22bb are set so as not to cause a problem of junction resistance in a junction diode between the p⁺ layer 23a and the Si pillar 7a and a junction diode between the n⁺ layer 23b and the Si pillar 7b. The SiGe layers 22aa and 22bb may be other semiconductor material layers made of a semiconductor material that satisfies conditions under which the problem of junction resistance does not occur and that has a higher oxidation rate than the Si pillars 7a and 7b. The SiGe layer 22aa and the SiGe layer 22bb may be different semiconductor material layers. When one or both of the Si pillars 7a and 7b, which are semiconductor pillars, are formed by using a semiconductor material other than Si, the SiGe layers 22aa and 22bb may be other semiconductor material layers made of a semiconductor material that satisfies conditions under which the problem of junction resistance does not occur and that has a higher oxidation rate than the Si pillars 7a and 7b.

In this embodiment, the SiO₂ layers 26a and 26b serving as etching masks for the gate conductor layers are formed after discharging the poly Si layer 16 serving as a dummy gate material layer. However, the SiO₂ layers 26a and 26b serving as etching masks for the gate conductor layers may be formed after forming a HfO₂ layer serving as a gate insulating layer, and a TiN layer and a W layer serving as gate conductor layers without forming the poly Si layer 16. The TiN layer and the W layer serving as gate conductor layers may be then etched by using the SiO₂ layers 26a and 26b as masks. In this case, the SiO₂ layers 26a and 26b are formed on the side surfaces of the p⁺ layer 23a and the n⁺ layer 23b.

In FIGS. 1EA to 1EC, the SiO₂ layers 18a and 18b are formed directly on the poly Si layer 16. However, the SiO₂ layers 18a and 18b may be formed after a SiN layer is formed on the poly Si layer 16. In the process of discharging the poly Si layer 16 illustrated in FIGS. 1KA to 1KC, the SiN layer is left connected to the bottom portions of the SiGe layers 22a and 22b. The SiN layer is then oxidized to form SiO₂ layers only on the exposed side surfaces of the SiGe layers 22a and 22b. The SiO₂ layers serve as etching masks for etching the TiN layer 29 and the W layer 30. The left SiN layer functions as an insulating layer for preventing short circuiting between the p⁺ layer 23a and the n⁺ layer 23b and the TiN layer 29a and the W layer 30a. The SiN layer may be another insulating material layer.

In FIGS. 1RA to 1RC, impurity layers containing an acceptor or donor impurity are not formed in the top portions of the Si pillars 7a and 7b that face the p⁺ layer 23a and the n⁺ layer 23b. However, impurity layers may be formed by, for example, diffusing, in the top portions of the Si pillars 7a and 7b, the acceptor or donor impurity of the p⁺ layer 23a and the n⁺ layer 23b through the thermal process until the final process. The formation of the impurity layers in the top portions of the Si pillars 7a and 7b may be performed by adding the acceptor or donor impurity to the SiGe layers 22a and 22b.

In FIGS. 1QA to 1QC, the W layer 30 is etched by using the SiO₂ layers 24a, 26a, 24b, and 26b as masks. However, the outer periphery of the TiN layer 29 may be formed outside the outer peripheries of the SiO₂ layers 26a and 26b in plan view, and the TiN layer 29 and the W layer 30 may be etched. One or both of the TiN layer 29 and the W layer 30 may be composed of multiple other conductor material layers.

In FIGS. 1RA to 1RC, the contact holes 36a and 36b are formed on the SiO₂ layers 24a and 24b while the SiO₂ layers 24a and 24b are left on the p⁺ layer 23a and the n⁺ layer 23b. However, the contact holes 36a and 36b may be formed after discharging the SiO₂ layers 24a and 24b and embedding conductor layers made of, for example, metal or alloy therein. In this case, the bottom portions of the contact holes may be located on the upper surfaces of the conductor layers made of, for example, metal or alloy.

In FIGS. 1LA to 1LC, the SiO₂ layers 27a and 27b are formed on the side surfaces of the Si pillars 7a and 7b. In FIGS. 1MA to 1MC, the SiO₂ layers 27a and 27b are discharged. However, the HfO₂ layer 28, the TiN layer 29, and the W layer 30 may be continuously formed without discharging the SiO₂ layers 27a and 27b.

This embodiment has the following features.

1. The p⁺ layer 23a is self-aligned with the Si pillar 7a. Similarly, the n⁺ layer 23b is self-aligned with the Si pillar 7b. Since the p⁺ layer 23a and the n⁺ layer 23b are formed inside the recessed portions 20a and 20bb self-aligned with the Si pillars 7a and 7b, the distance between the Si pillars 7a and 7b can be shortened without contact between the SiO₂ layer 18a and the SiO₂ layer 18b in FIGS. 1EA to 1EC. This can form a high-density SGT-including circuit. The p⁺ layer 23a and the n⁺ layer 23b are then formed to cover the entire top portions of the Si pillars 7a and 7b. This configuration can increase the contact surface between the p⁺ layer 23a and the Si pillar 7a and between the n⁺ layer 23b and the Si pillar 7b. This can provide a high-density circuit including a SGT with a small diode junction resistance.
2. As shown in FIGS. 1QA to 1QC, the W layer 30a and the TiN layer 29a, which are gate line conductor layers, are formed by using the SiO₂ layers 24a, 26a, 24b, and 26b and the mask material layer 33 as etching masks. The mask material layer 33 is formed by lithography. The W layer 30a below the mask material layer 33 is used to connect the W layer 30a below the SiO₂ layer 26a and the W layer 30a below the SiO₂ layer 26b. The mask material layer 33 at least partially overlaps the SiO₂ layers 24a and 24b in plan view. Thus, mask misalignment in the lithography process for forming the mask material layer 33 does not hinder SGT circuit densification. The W layer 30a and the TiN layer 29a, which are gate line conductor layers, below the SiO₂ layers 26a and 26b are self-aligned with the SiO₂ layers 26a and 26b. The W layer 30a and the TiN layer 29a below the SiO₂ layers 26a and 26b are also self-aligned with the p⁺ layer 23a and the n⁺ layer 23b and the Si pillars 7a and 7b. This configuration can provide a high-density SGT circuit. 3. In this embodiment, the CMOS inverter circuit including two Si pillars 7a and 7b is described as an example. In the SGT formed in one Si pillar 7a, the TiN layer 29a and the W layer 30a, which are gate line conductor layers, are self-aligned with the p⁺ layer 23a. The p⁺ layer 23a with a small diode junction resistance is formed. Therefore, the present invention can also be applied to a circuit including an SGT(s) formed in one or more Si pillars. This can improve the density and performance of various SGT-including circuits.

### Second Embodiment

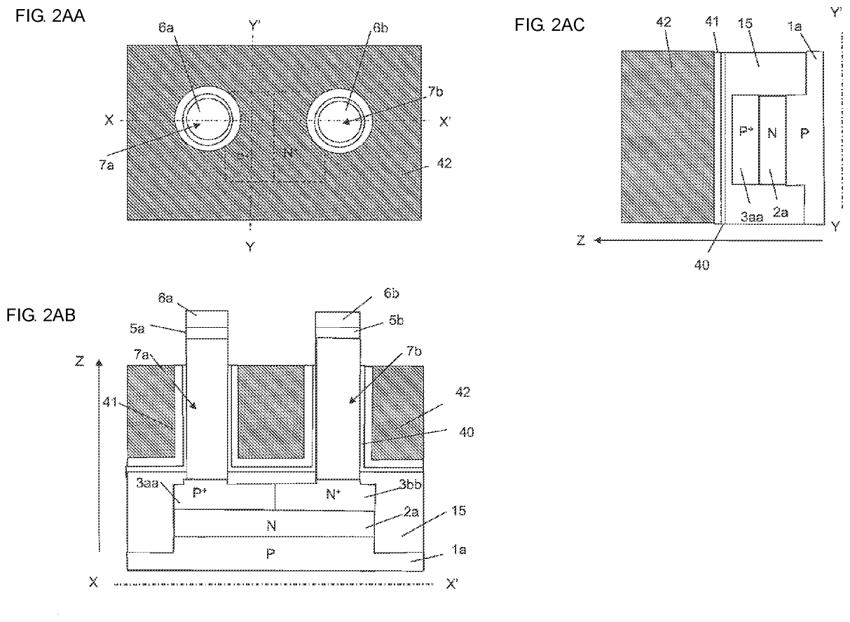

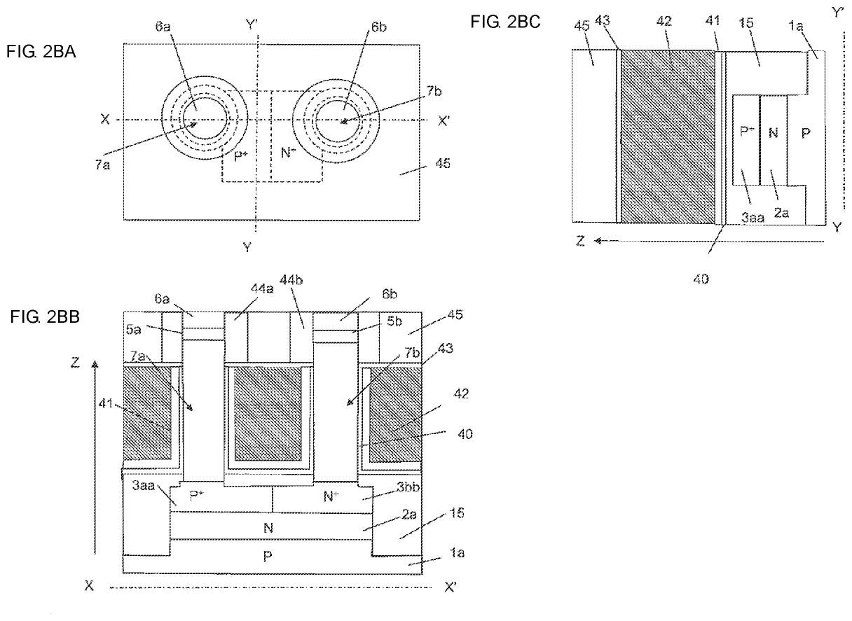

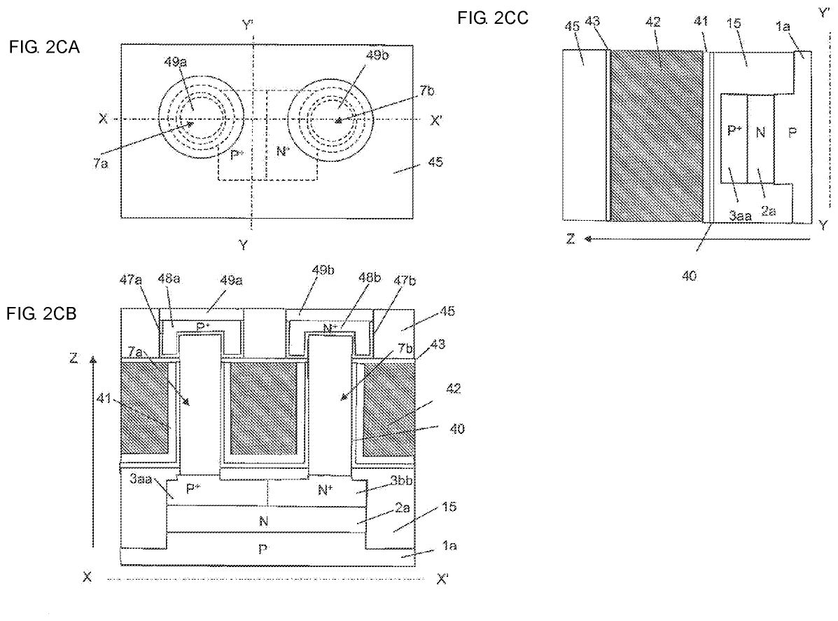

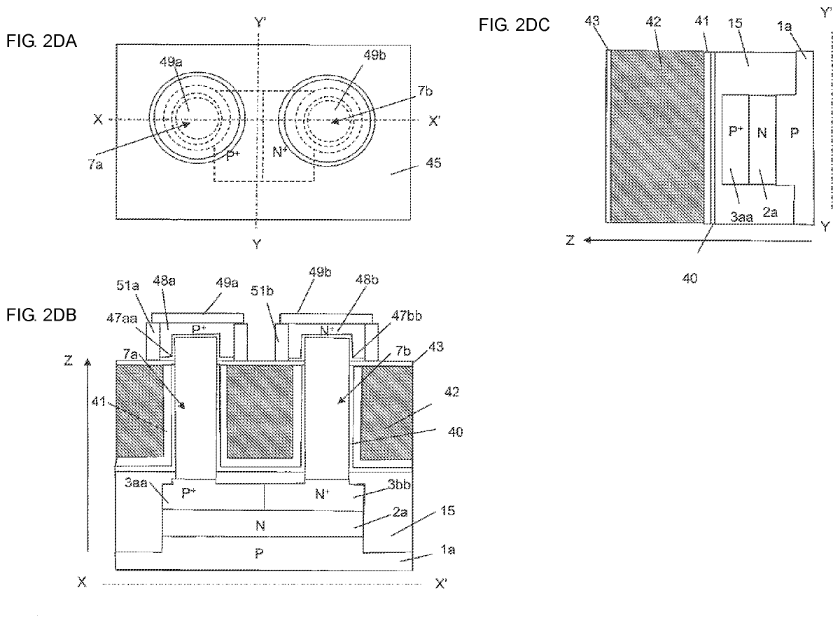

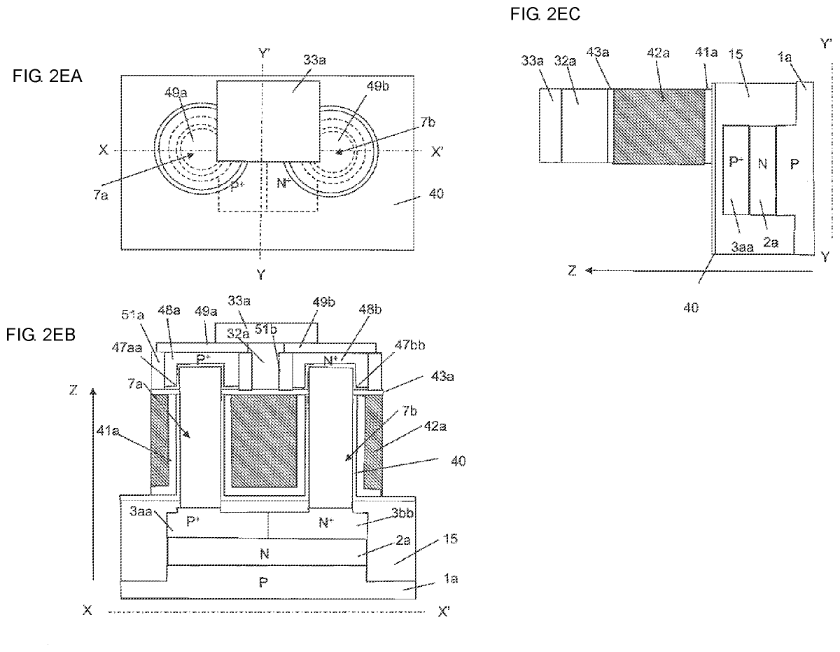

FIGS. 2AA to 2CC illustrate a method for producing an SGT-including CMOS inverter circuit according to a second embodiment of the present invention. The figures suffixed with letter A are plan views, the figures suffixed with letter B are cross-sectional views taken along line X-X′ in the respective figures suffixed with letter A, and the figures suffixed with letter C are cross-sectional views taken along line Y-Y′ in the respective figures suffixed with letter A.

The same processes as those in FIGS. 1AA to 1CC are carried out. As shown in FIGS. 2AA to 2AC, a SiO₂ layer 15 is formed on the outer peripheries of the Si pillars 7a and 7b so as to have an upper surface positioned higher than the upper surfaces of the p⁺ layer 3aa and the n⁺ layer 3bb. A HfO₂ layer (not shown), a TiN layer (not shown), and a W layer (not shown) are then deposited on the entire surface. The HfO₂ layer, the TiN layer, and the W layer are then polished by CMP so as to have upper surfaces flush with the upper surfaces of the SiN layers 6a and 6b. The HfO₂ layer, the TiN layer, and the W layer are then etched by RIE so as to have upper surfaces positioned adjacent to the upper portions of the Si pillars 7a and 7b to form a HfO₂ layer 40, a TiN layer 41, and a W layer 42. A thin SiO₂ layer is preferably formed on the side surfaces of the Si pillars 7a and 7b before the HfO₂ layer is deposited.

Next, as shown in FIGS. 2BA to 2BC, a SiN layer 43 is formed on the HfO₂ layer 40, the TiN layer 41, and the W layer 42 on the outer peripheries of the Si pillars 7a and 7b. In accordance with the same method as that in FIGS. 1EA to 1FC, SiO₂ layers 44a and 44b are formed on the side surfaces of the top portions of the Si pillars 7a and 7b, the SiO₂ layers 5a and 5b, and the SiN layers 6a and 6b by self-alignment, and an AlO layer 45 is formed on the outer peripheries of the SiO₂ layers 44a and 44b by self-alignment.

Next, the same processes as those in FIGS. 1GA to 1JC are carried out. As shown in FIGS. 2CA to 2CC, a SiGe layer 47a, a p⁺ layer 48a, and a SiO₂ layer 49a are formed so as to cover the top portion of the Si pillar 7a. Similarly, a SiGe layer 47b, an n⁺ layer 48b, and a SiO₂ layer 49b are formed so as to cover the top portion of the Si pillar 7b.

Next, as shown in FIGS. 2DA to 2DC, the AlO layer 45 is discharged. The exposed side surfaces of the p⁺ layer 48a and the n⁺ layer 48b are oxidized to form SiO₂ layers 51a and 51b. Since the SiGe layers 47a and 47b inside the SiO₂ layers 51a (an example of the third oxide layer in Claims) and 51b in plan view thus remain unoxidized, SiGe layers 47aa and 47bb cover the top portions of the Si pillars 7a and 7b and remain on the surrounding area.

Next, a SiN layer (not shown) is formed on the outer peripheries of the SiO₂ layers 51a and 51b in plan view. As shown in FIGS. 2EA to 2EC, a mask material layer 33a and a SiN layer 32a below the mask material layer 33a are then formed by the same process as that in FIGS. 1QA to 1QC. The SiN layer 43, the W layer 42, and the TiN layer 41 are etched by using the mask material layer 33a and the SiO₂ layers 49a, 49b, 51a, and 51b as masks to form a SiN layer 43a, a W layer 42a, and a TiN layer 41a.

Next, an SGT-including CMOS inverter circuit is formed on a p layer substrate 1a as in the first embodiment by carrying out the same process as that in FIGS. 1RA to 1RC.

This embodiment has the following features.

1. In the first embodiment, the poly Si layer 16 serving as a dummy gate material layer is formed as shown in FIGS. 1DA to 1DC, the poly Si layer 16 is then discharged as shown in FIGS. 1KA to 1KC, and the TiN layer 29 and the W layer 30 serving as gate conductor layers are formed as shown in FIGS. 1NA to 1NC. The TiN layer 29 and the W layer 30 serving as gate conductor layers are formed after the SiO₂ layers 26a and 26b serving as etching masks are formed. The SiO₂ layers 27a and 27b on the side surfaces of the Si pillars 7a and 7b are discharged, and at the same time, the SiO₂ layers 26a and 26b are etched. In the first embodiment, the SiO₂ layers 26a and 26b thus need to remain thick so as to function as an etching mask after etching. In this embodiment, however, no dummy gate material layer is formed. In this embodiment, the number of processes can thus be reduced compared with the first embodiment.
2. In this embodiment, there is no process of etching the SiO₂ layers 27a and 27b on the side surfaces of the Si pillars 7a and 7b, unlike the first embodiment. This allows formation of thin SiO₂ layers 51a and 51b. The distance between the adjacent Si pillars 7a and 7b can be thus shortened compared with the first embodiment. This configuration can provide a highly integrated SGT circuit.
3. In the first embodiment, as shown in FIGS. 1RA to 1RC, the distance between the p⁺ layer 23a, which is a source of the SGT in the vertical direction, and the TiN layer 29a, which is a gate conductor layer, corresponds to the thickness of the SiO₂ layer 26a and the HfO₂ layer 28. The SiO₂ layer 26a functions as an etching mask, and the HfO₂ layer 28 functions as a gate insulating layer. In this embodiment, as shown in FIGS. 2EA to 2EC, the distance between the p⁺ layer 48a, which is a source of the SGT in the vertical direction, and the TiN layer 41a, which is a gate conductor layer, can be independently determined only by the thickness of the SiN layer 43a (the SiGe layer 47aa can be converted into a p⁺ layer when containing an acceptor impurity, and the SiGe layer can be converted into a p⁺ layer when the acceptor impurity of the p⁺ layer 48a is diffused in the SiGe layer through thermal diffusion). In this embodiment, the distance between the p⁺ layer 48a and the gate TiN layer 41a can be set more easily than in the first embodiment, as described above.

### Third Embodiment

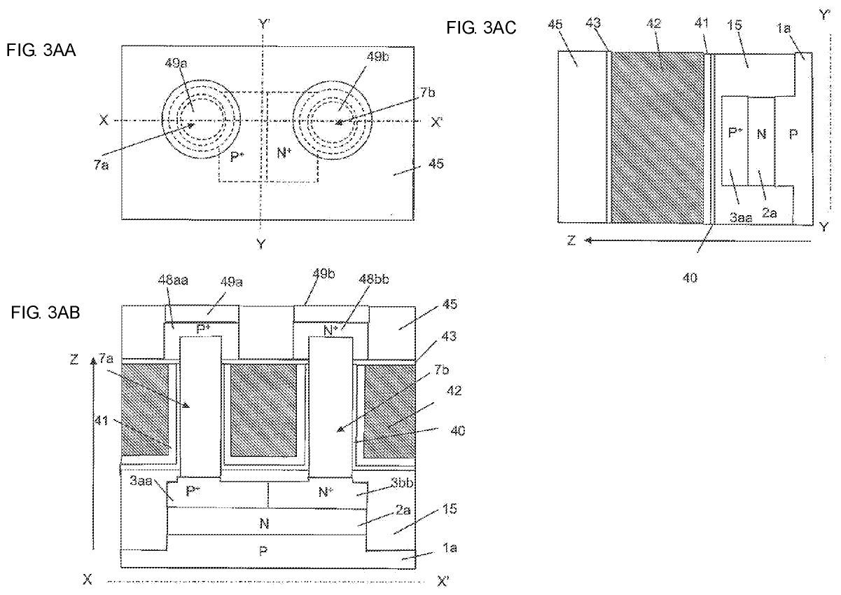

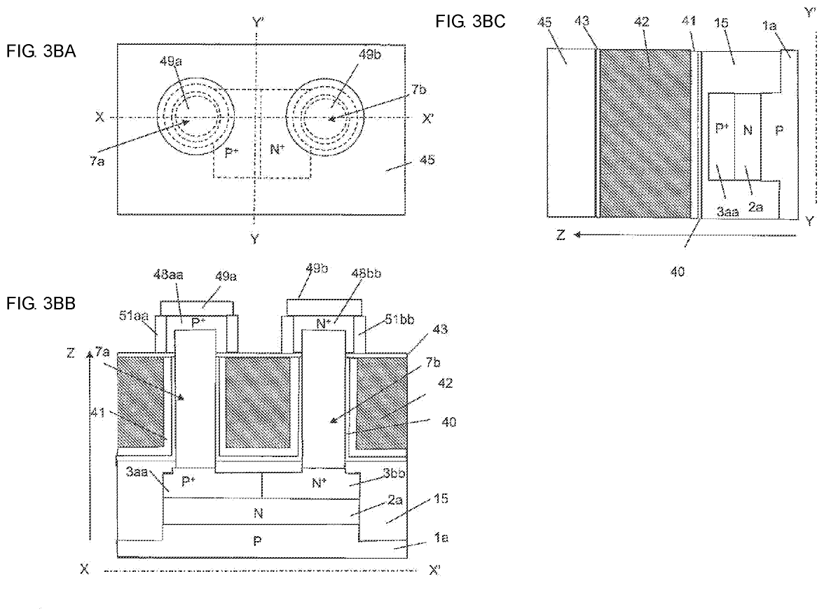

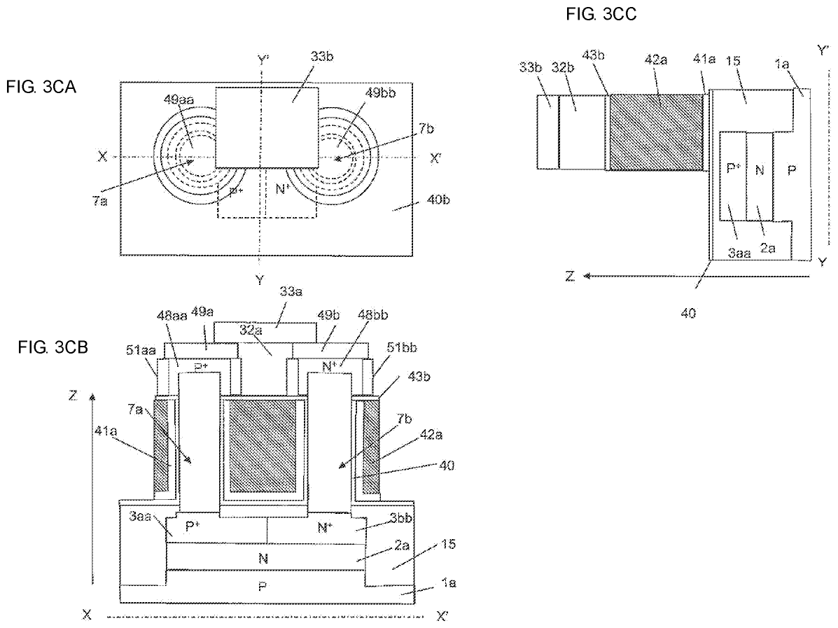

FIGS. 3AA to 3CC illustrate a method for producing an SGT-including CMOS inverter circuit according to a third embodiment of the present invention. The figures suffixed with letter A are plan views, the figures suffixed with letter B are cross-sectional views taken along line X-X′ in the respective figures suffixed with letter A, and the figures suffixed with letter C are cross-sectional views taken along line Y-Y′ in the respective figures suffixed with letter A.

The same processes as those in FIGS. 2AA to 2CC are carried out except that neither the SiGe layer 47a or 47b is formed. As shown in FIGS. 3AA to 3AC, a p⁺ layer 48aa and an n⁺ layer 48bb are thus formed so as to cover the top portions of Si pillars 7a and 7b. The p⁺ layer 48aa and the n⁺ layer 48bb are self-aligned with the Si pillars 7a and 7b as in the embodiments described above.

Next, as shown in FIGS. 3BA to 3BC, the side surfaces of the p⁺ layer 48aa and the n⁺ layer 48bb are oxidized to form SiO₂ layers 51aa and 51bb.

Next, the same process as that in FIGS. 2EA to 2EC is carried out. As shown in FIGS. 3CA to 3CC, a TiN layer 41a and a W layer 42a self-aligned with the p⁺ layer 48aa and the n⁺ layer 48bb are formed accordingly.

Next, an SGT-including CMOS inverter circuit is formed on a p layer substrate 1a as in the first embodiment and the second embodiment by carrying out the same process as that in FIGS. 1RA to 1RC.

This embodiment has the following features.

In the first embodiment, as shown in FIGS. 1KA to 1KC, the SiGe layers 22a and 22b having a higher oxidation rate than the side surfaces of the Si pillars 7a and 7b are formed outside the p⁺ layer 23a and the n⁺ layer 23b. This is because the SiO₂ layers 26a and 26b need to remain outside the p⁺ layer 23a and the n⁺ layer 23b after the SiO₂ layers 27a and 27b on the side surfaces of the Si pillars 7a and 7b are discharged as shown in FIGS. 1LA to 1LC and FIGS. 1MA to 1MC. In this embodiment, however, the SiO₂ layers 51aa and 51bb are formed by oxidizing only the exposed side surfaces of the p⁺ layer 48aa and the n⁺ layer 48bb without oxidizing the side surfaces of the Si pillars 7a and 7b at the same time. The p⁺ layer 48aa and the n⁺ layer 48bb are any oxidizable semiconductor material layers. Unlike the second embodiment, there is no need to form thin SiGe layers 47a and 47b. The number of processes can be thus reduced.

### Fourth Embodiment

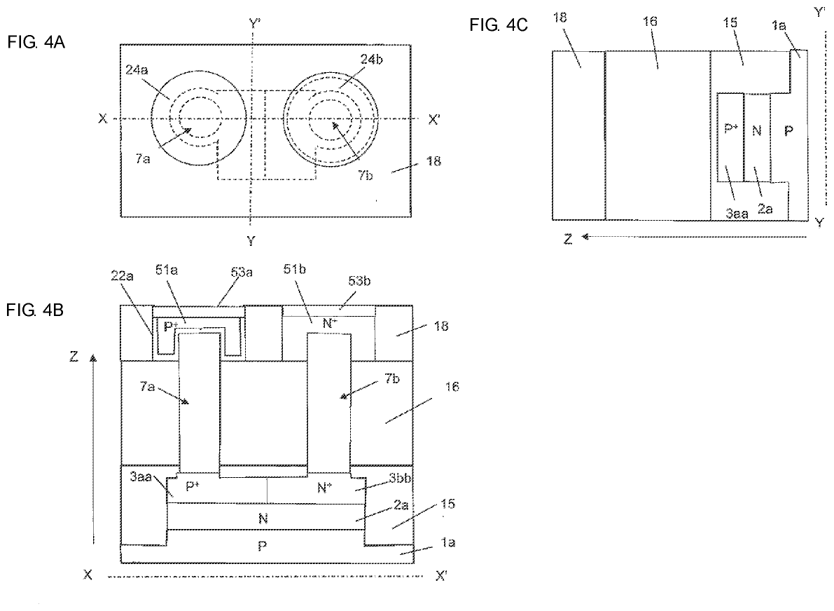

FIGS. 4A to 4C illustrate a method for producing an SGT-including CMOS inverter circuit according to a fourth embodiment of the present invention. The figure suffixed with letter A is a plan view, the figure suffixed with letter B is a cross-sectional view taken along line X-X′ in the figure suffixed with letter A, and the figure suffixed with letter C is a cross-sectional view taken along line Y-Y′ in the respective figure suffixed with letter A.

As shown in FIGS. 4A to 4C, the SiGe layer 22b used in the first embodiment is not formed outside the n⁺ layer 51b when the p⁺ layer is made of a semiconductor material composed of Si, and the n⁺ layer is a semiconductor layer made of SiGe in the first embodiment.

However, in forming the n⁺ layer 51b, the composition ratio between Si and Ge may be changed in the early stage of SiGe deposition such that an oxide layer that is preferred in view of the oxidation rate of the Si pillar 7b will be formed outside the n⁺ layer 51b in a later process. The same applies to the case where the n⁺ layer 51b is made of a compound semiconductor material composed of at least two elements.

This embodiment has the following features.

In this embodiment, the n⁺ layer 51b is made of a SiGe material having a higher oxidation rate than the side surfaces of the Si pillars 7a and 7b, and there is thus no need of the additional SiGe layer 22b shown in the first embodiment. In this embodiment, the number of processes can thus be reduced compared with the first embodiment. If the p⁺ layer 51a is a semiconductor material layer having a higher oxidation rate than the side surfaces of the Si pillars 7a and 7b, there is no need to form a semiconductor material layer, such as a SiGe layer, on the p⁺ layer 51a.

In the embodiments described above, the Si pillars made of silicon are used. However, the technical idea of the present invention can also be applied to SGTs partly or entirely composed of a semiconductor material other than silicon.

In the first embodiment, the case where a single SGT is formed in each of the Si pillars 7a and 7b is described. However, the present invention can also be applied to circuit formation for forming multiple SGTs in a single semiconductor pillar. This can be applied to other embodiments according to the present invention.

In the embodiments described above, a silicon-on-insulator (SOI) substrate having an insulating substrate can also be used instead of the p layer substrate 1. In this case, the n layer 2 may be or may not be disposed.

In the embodiments described above, the case where the Si pillars 7a and 7b have a circular shape in plan view is described. However, it is apparent that the Si pillars 7a and 7b may have an elliptical or rectangular shape.

In the first embodiment, the TiN layer 29a and the W layer 30a connected to the TiN layer 29a are used as gate conductor layers. However, the gate conductor layers may be layers made of other metals or alloys, or conductor material layers made of low-resistance semiconductors. The gate conductor layers may be conductor layers composed of one or more layers. The same applies to other embodiments according to the present invention.

In the first embodiment, the etching mask material layer 33 may be a resist layer for lithography, or an organic or inorganic material layer composed of one or more layers. The same applies to other embodiments according to the present invention.

In the first embodiment, the HfO₂ layer 28 is used as a gate insulating layer. However, the insulating layer is not limited to HfO₂ and may be made of other insulating materials and composed of one or more layers. The same applies to other embodiments according to the present invention.

In the first embodiment, the case where the side surfaces of the Si pillars 7a and 7b have a columnar shape vertical to the plane of the p layer substrate 1 is described. However, the side surfaces of the Si pillars 7a and 7b may have a trapezoidal shape or a barrel shape as long as the structure in each embodiment is realized. The same applies to other embodiments according to the present invention.

The SGT has a gate insulating layer on the outer periphery of a semiconductor pillar and has a gate conductor layer on the outer periphery of the gate insulating layer. A flash memory device including a conductor layer electrically floating between the gate conductor layer and the gate insulating layer is also one form of the SGT. The technical idea of the present invention can also be applied to such a flash memory device.

In the embodiments, the cases where only SGT is formed in a semiconductor pillar are described. However, the technical idea of the present invention can also be applied to a method for producing a semiconductor device incorporating an SGT and other devices, such as a photodiode, a magnetic random access memory (MRAM), a phase change memory (PCM), and a resistance-change random access memory (ReRAM).

The embodiments are described by using an SGT in which the upper and lower impurity regions each serving as a source or drain contain impurity atoms with the same polarity. However, the present invention can also be applied to a tunneling SGT including impurity atoms with different polarities. Similarly, the present invention can also be applied to an SGT in which one or both of the source and the drain are formed of a Schottky diode.

Various embodiments and modifications can be made in the present invention without departing from the broad spirit and scope of the present invention. The embodiments described above are for illustrating examples of the present invention and do not limit the scope of the present invention. The examples described above and modifications can be freely combined with each other. Even if some elements are removed from the embodiments as necessary, the embodiments are also within the technical idea of the present invention.

The method for producing an SGT-including semiconductor device according to the present invention is useful for achieving a high-density, high-performance SGT-including pillar-shaped semiconductor device.

What is claimed is:

1. A method for producing a pillar-shaped semiconductor device, the method comprising:
a step of forming a first semiconductor pillar on a substrate, the first semiconductor pillar having a first material layer on a top portion thereof;
a step of forming a second material layer in plan view around a side surface of the first material layer and a side surface of the top portion of the first semiconductor pillar;
a step of forming a third material layer on an outer periphery of the second material layer;
a step of discharging the first material layer and the second material layer to form a first recessed portion around the top portion of the first semiconductor pillar;
a step of forming a first semiconductor layer composed of one or more layers in the first recessed portion, the first semiconductor layer being in contact with a side surface of the first recessed portion and having an upper surface positioned lower than an upper surface of the first recessed portion;
a step of forming a fourth material layer on the first semiconductor layer, the fourth material layer having an upper surface flush with an upper surface of the third material layer;
a step of discharging the third material layer;
a step of oxidizing an exposed surface layer of the first semiconductor layer to form a first oxide layer; and
a step of etching a conductor layer around the first semiconductor pillar by using the fourth material layer and the first oxide layer as masks to form a first gate conductor layer, the conductor layer being composed of one or more layers,
wherein the first semiconductor layer functions as a source or drain, and a first gate insulating layer is disposed between the first semiconductor pillar and the first gate conductor layer.

2. The method for producing a pillar-shaped semiconductor device according to claim 1, wherein
at least the surface layer of the first semiconductor layer is made of a material having a higher oxidation rate than the first semiconductor pillar.

3. The method for producing a pillar-shaped semiconductor device according to claim 1, wherein
the first semiconductor layer includes a second semiconductor layer and a third semiconductor layer from outside,
the second semiconductor layer is made of a material having a higher oxidation rate than the first semiconductor pillar, and
at least the third semiconductor layer contains a donor or acceptor impurity.

4. The method for producing a pillar-shaped semiconductor device according to claim 1, comprising:
a step of forming a dummy gate material layer around the first semiconductor pillar;
a step of forming the second material layer and the third material layer on or above the dummy gate material layer;
a step of discharging the first material layer and the second material layer to form the first recessed portion, and discharging the dummy gate material layer after forming the first semiconductor layer and the fourth material layer;
a step of forming the first oxide layer on the exposed surface layer of the first semiconductor layer and, at the same time, forming a second oxide layer on the exposed surface layer of the first semiconductor pillar;
a step of forming the first gate insulating layer and the conductor layer around the first semiconductor pillar; and
a step of etching the conductor layer around the first semiconductor pillar by using the fourth material layer and the first oxide layer as masks to form the first gate conductor layer.

5. The method for producing a pillar-shaped semiconductor device according to claim 4, comprising:
a step of forming a first insulating layer on the dummy gate material layer before forming the second material layer; and
a step of etching the first insulating layer and the conductor layer around the first semiconductor pillar by using the fourth material layer and the first oxide layer as masks to form the first gate conductor layer.

6. The method for producing a pillar-shaped semiconductor device according to claim 1, comprising:
a step of exposing the first material layer and the top portion of the first semiconductor pillar and forming the first gate insulating layer and the conductor layer around a side surface of the semiconductor pillar below the top portion of the first semiconductor pillar;
a step of forming a second insulating layer on the conductor layer; and
a step of forming the second material layer on the second insulating layer.

7. The method for producing a pillar-shaped semiconductor device according to claim 6, comprising:
a step of forming the first semiconductor layer and the fourth material layer after forming the second insulating layer;
a step of oxidizing a side surface of the first semiconductor layer to form a third oxide layer; and
a step of etching the second insulating layer and the conductor layer by using the first material layer and the third material layer as masks to form the first gate conductor layer.

8. The method for producing a pillar-shaped semiconductor device according to claim 1, comprising:
a step of forming a first mask material layer on the fourth material layer, the first mask material layer at least partially overlapping the fourth material layer in plan view; and
a step of etching the conductor layer by using the first oxide layer, the fourth material layer, and the first mask material layer as masks to form the first gate conductor layer.

9. The method for producing a pillar-shaped semiconductor device according to claim 1, comprising:
a step of forming a second semiconductor pillar adjacent to the first semiconductor pillar;
a step of forming a second recessed portion around a top portion of the second semiconductor pillar by the same step as that of forming the first recessed portion;
a step of forming a fourth semiconductor layer in the second recessed portion so as to cover the top portion of the second semiconductor pillar by the same step as that of forming the first semiconductor layer, and forming a fifth material layer on the fourth semiconductor layer, the fifth material layer having an upper surface flush with an upper surface of the fourth material layer;
a step of oxidizing the first semiconductor layer to form the first oxide layer and, at the same time, oxidizing the fourth semiconductor layer to form a third oxide layer; and
a step of etching the conductor layer by using the first oxide layer, the fourth material layer, the fifth material layer, and the third oxide layer as masks to form the first gate conductor layer.

10. The method for producing a pillar-shaped semiconductor device according to claim 9, comprising:
a step of forming a second mask material layer on the fourth material layer and the fifth material layer, the second mask material layer at least partially overlapping the fourth material layer and the fifth material layer in plan view; and
a step of etching the conductor layer by using the first oxide layer, the fourth material layer, the third oxide layer, the fifth material layer, and the second mask material layer as masks to form the first gate conductor layer.
